(19) United States
(12) Patent Application Publication
(10) Pub. No.: US 2019/0221652 A1
(43) Pub. Date: Jul. 18, 2019

(54) SEMICONDUCTOR ELECTRONIC DEVICE WITH TRENCH GATE AND MANUFACTURING METHOD THEREOF

(71) Applicant: STMICROELECTRONICS S.R.L., Agrate Brianza (IT)

(72) Inventors: Davide Giuseppe PATTI, Mascalucia (IT); Marco SAMBI, Cornaredo (IT); Fabrizio Fausto Renzo TOIA, Busto Arsizio (IT); Simone Dario MARIANI, Vedano al Lambro (IT); Elisabetta PIZZI, Limbiate (IT); Giuseppe BARILLARO, Pisa (IT)

(21) Appl. No.: 16/247,358

(22) Filed: Jan. 14, 2019

(30) Foreign Application Priority Data
Jan. 15, 2018 (IT) 102018000000928

(51) Int. Cl. H01L 29/423; H01L 29/78; H01L 29/739; H01L 29/66; H01L 21/265

(52) U.S. Cl. CPC H01L 29/42364; H01L 29/7813; H01L 21/26533; H01L 29/4236; H01L 29/66734; H01L 29/7397

(57) ABSTRACT

A vertical-conduction semiconductor electronic device includes: a semiconductor body; a body region in the semiconductor body; a source terminal in the body region; a drain terminal spatially opposite to the source region; and a trench gate extending in depth in the semiconductor body through the body region and the source region. The trench gate includes a dielectric region of porous silicon oxide buried in the semiconductor body, and a gate conductive region extending between the dielectric region of porous silicon oxide and the first side.

### BACKGROUND

### Technical Field

The present disclosure relates to a semiconductor electronic device with trench gate and to a method for manufacturing the semiconductor electronic device with trench gate.

### Description of the Related Art

Vertical-conduction power metal-oxide semiconductor field effect transistors (MOSFETs) are known that have a buried-gate region or trench-gate region.

For instance, the patent document No. US 2015/0206968 describes a vertical-channel laterally diffused metal oxide semiconductor (LDMOS) semiconductor device, in which a gate trench extends in depth in a semiconductor body and comprises a conductive region, of doped polysilicon, surrounded and electrically insulated from the semiconductor body by a dielectric region (made, for example, of silicon oxide or silicon nitride).

The dielectric region may be formed by a process of deposition, for example liquid-phase deposition (LPD), or else by thermal growth of an oxide. Both of the processes present some intrinsic limits. For instance, deposition of a dielectric layer may cause crystallographic interface stresses that may jeopardize electrical operation of the device (e.g., generating traps for the charge carriers), whereas thermal growth typically involves the use of structures for protecting the surface regions in which growth of a thermal oxide is undesirable or counterproductive.

### BRIEF SUMMARY

One or more embodiments are directed to a process for manufacturing an electronic device with trench gate that will overcome at least some of the disadvantages of the prior art.

According to the present disclosure, a semiconductor electronic device and a method for manufacturing the semiconductor electronic device are provided.

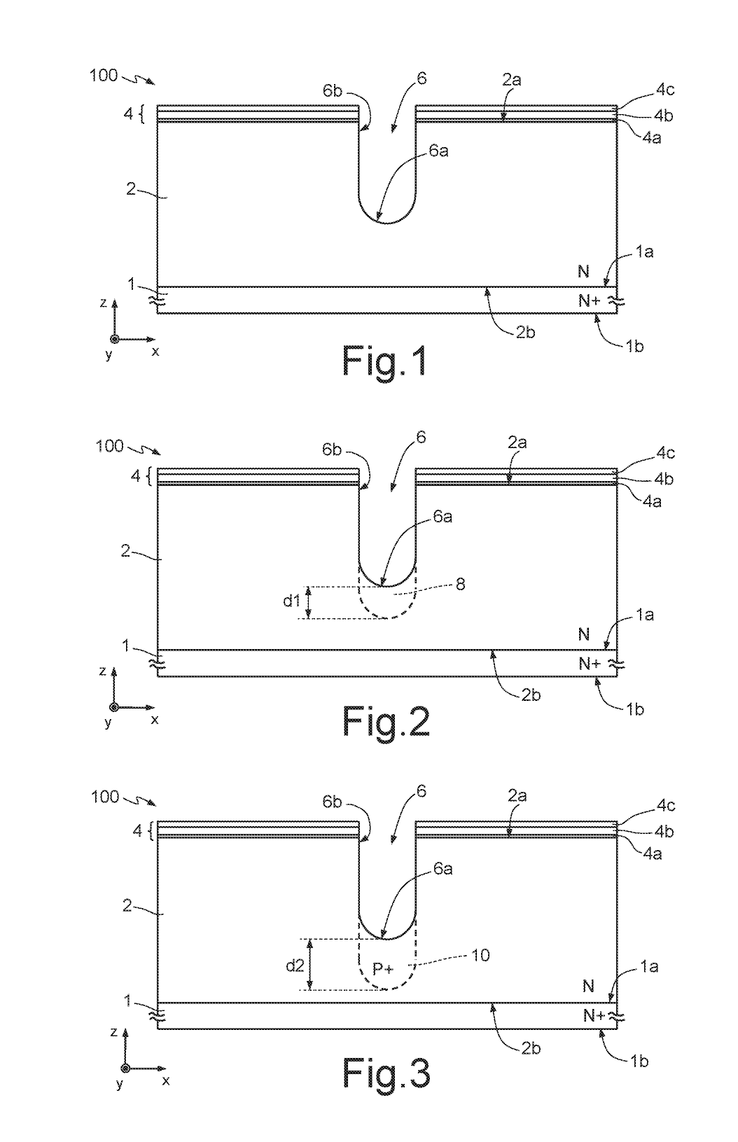

For a better understanding of the present disclosure, preferred embodiments thereof are now described, purely by way of non-limiting example, with reference to the attached drawings, wherein FIGS. 1-13 illustrate, in lateral sectional view, manufacturing steps for the production of a semiconductor electronic device with trench region, according to an embodiment of the present disclosure.

According to the present disclosure, a power device is provided, in particular a MOS transistor with source electrode on a front side of the device, drain electrode on a back side of the device, and trench gate, which extends from the front side towards the back side.

### BRIEF DESCRIPTION OF THE SEVERAL VIEWS OF THE DRAWINGS

The steps for manufacturing the electronic device according to the present disclosure are described in the following, with reference to FIGS. 1-13. FIGS. 1-13 illustrate the electronic device in lateral sectional view, in a system of spatial coordinates defined by mutually orthogonal axes X, Y, and Z.

### DETAILED DESCRIPTION

In particular, the present disclosure describes manufacturing steps of interest for the disclosure (i.e., regarding construction of a trench gate provided with an internal insulation region). Further elements of the electronic device (e.g., edge regions or other structures), which may be of a per se known type, are not described and illustrated here in the figures.

FIG. 1 illustrates a wafer 100 comprising a substrate 1, in particular of monocrystalline silicon, having a first conductivity type (here, of an N type) and a first doping concentration (e.g., higher than 10¹⁹ at./cm³). The substrate 1 is delimited on a first side 1a and on a second side 1b opposite to one another along the axis Z.

On the substrate 1, a structural layer or region 2 is formed, for example by epitaxial growth of silicon, having the first conductivity type (N) and a concentration of dopants lower than that of the substrate 1 (e.g., comprised between 1·10¹⁵ and 5.10¹⁶ ions/cm³). The structural region 2 has a thickness, along Z, that is chosen on the basis of the voltage class in which the electronic device is to operate, and is, for example, comprised approximately between 1·5 μm and 100 μm.

The structural region 2 is delimited by a first side 2a and a second side 2b opposite to one another in the direction Z. The second side 2b of the structural region 2 coincides with the first side 1a of the substrate 1.

According to alternative embodiments (not illustrated), one or more further structural regions, which are, for example, grown epitaxially and are similar to the structural region 2, may be formed between the first side 1a of the substrate 1 and the second side 2b of the structural region 2.

On the first side 2a of the structural layer 2, a mask multilayer 4 is then formed, which includes: a first mask layer 4a, in contact with the first side 2a, made, for example, of silicon oxide grown via thermal oxidation with a thickness comprised between 5 nm and 100 nm; a second mask layer 4b, immediately on top of the first mask layer 4a, made, for example, of silicon nitride with a thickness comprised between 10 nm and 1 μm; and a third mask layer 4c, immediately on top of the second mask layer 4b, made, for example, of tetraethyl orthosilicate (TEOS) or photoresist with a thickness comprised between 10 nm and 10 μm. The first mask layer 4a has the function of forming an interface between the structural layer 2, of silicon, and the second mask layer 4b, of silicon nitride, in order to prevent mechanical stress induced by silicon nitride and prevent nitriding of the surface of the silicon itself, which jeopardizes operation of the device. The second mask layer 4b forms a hard mask for a subsequent step of etching of the structural layer 2. The third mask layer 4c forms a further hard mask for the step of etching of the structural layer 2.

By photolithographic technique, the mask multilayer 4 is removed in regions of the wafer 100 where the trench gate is to be formed. Then etching is carried out, in particular of a dry type, for example reactive ion etching (ME), for selective removal of portions of the structural layer 2 exposed through the mask multilayer 4 and so as to form a trench 6 delimited by a bottom wall 6a and side walls 6b. The trench 6 has a depth, measured starting from the first side 2a of the structural layer 2 comprised, for example, between 1 and 2 μm.

In top plan view, in the plane XY, the trench 6 may be strip-shaped, with main extension along the axis Y ranging from a few microns to a few millimeters, and a width, along the axis X, comprised between 0.5 μm and 1·5 μm. Other layouts may be envisaged for the trench 6; for example, it may have, once again in view in the plane XY, a circular shape with a diameter comprised between 0.5 μm and 1·5 μm, or some other shape, for example, generically polygonal.

Next (FIG. 2), at the bottom wall 6a of the trench 6, it is formed an implanted region 8 having a second conductivity type (here, a conductivity of P+ type), for example by a step of ion implantation of boron. More in particular, a plurality of successive implantations (e.g., from one to three implantations) are carried out, each at a respective implantation energy but with the same dose of dopant atoms (or respective doses chosen in a limited range, for example not more than one order of magnitude). The implanted region 8 is thus formed, which extends from the bottom wall 6a of the trench 6 for a depth d₁, measured starting from the bottom wall 6a, of a few microns. The implantation dose is, by way of example, comprised between 5.10¹⁴ and 5.10¹⁵ at./cm³′ and the implantation energies are, by way of example, comprised between 100 keV and 1000 keV.

A subsequent rapid thermal process at a high temperature (also known as RTA or RTP), for example, comprised between 900° C. and 1150° C. for 30 seconds, activates the dopants of the implanted region 8 and enables minimal diffusion thereof in the structural layer 2, in particular in depth. A doped region 10 is thus formed (FIG. 3), having an extension d₂, measured starting from the bottom wall 6a, just a little greater than d₁ and of a few microns.

As an alternative to RTA or RTP, it is possible to carry out an oxidation process of an in situ steam generation (ISSG) type or, once again alternatively, an oxidation (of a wet or dry type) in an oven.

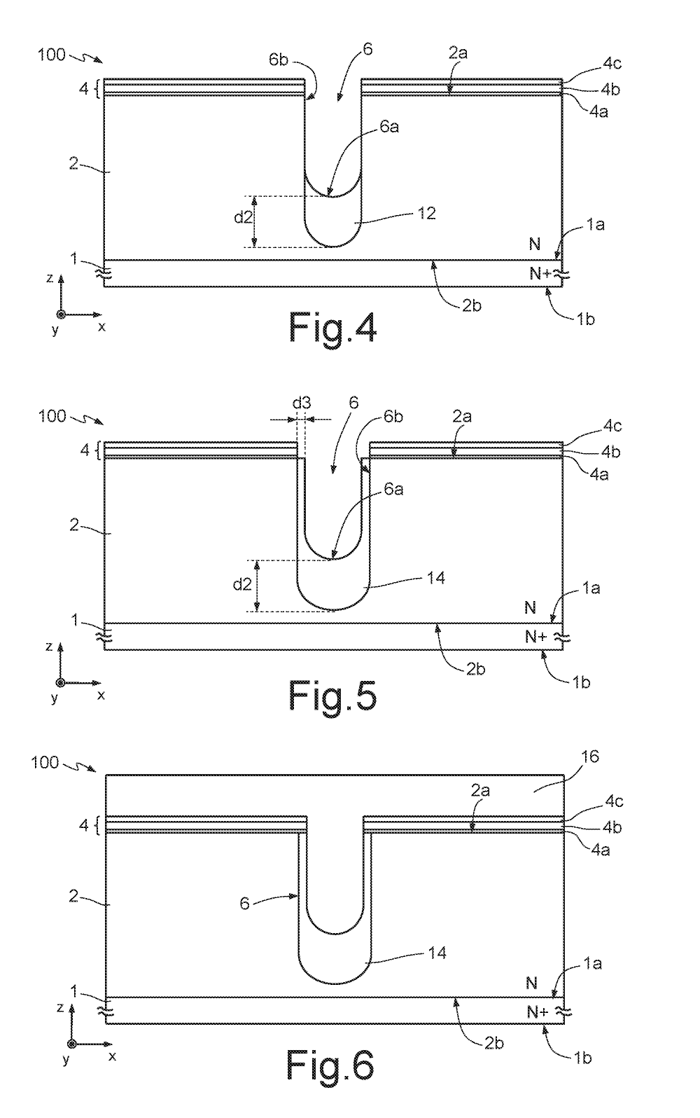

Next (FIG. 4), the doped region 10 is converted into a porous-silicon region 12.

In general, the structure of porous silicon, from a morphological standpoint, presents as an interconnected network of pores. The size, direction, position, and depth of the pores depend upon parameters set during formation thereof, as well as upon the conductivity type of the region in which the porous silicon is formed.

In fact, as is known, on the basis of the density and type of doping of the region in which the porous silicon is formed, the morphology of porous silicon differs. In the context of the present disclosure, according to the embodiment discussed previously, in the case of silicon of a P type, the mean diameter of the pores ranges between 1 nm and 100 nm, and the structure obtained is branched, highly interconnected, and homogeneous. As the dose of dopant for formation of the doped region 10 increases, the diameter of the pores and the distance between them increase. The present applicant has noted that the implantation dose affects both the rate of growth of porous silicon and the degree of porosity (in particular, the higher the dose of dopants, the greater the volume of the voids at the expense of the volume of full silicon).

The system used, for anodic etching of silicon, typically comprises a cell with three electrodes, one of which is represented by the crystalline-silicon wafer 100, which contains an aqueous electrolytic solution.

The wafer 100 is located at a positive (anode) potential with respect to the electrolytic solution; the front side of the wafer 100 (having the trench 6) is arranged directly in contact with the electrolytic solution. The electrolytic solution is typically made up of hydrogen fluoride (HF), deionized water, and ethanol. Other compounds may be used to improve wettability of the silicon surface exposed to etching, reducing the formation of hydrogen bubbles that are formed, during the electrochemical reaction, at the electrodes.

The characteristics of the porous-silicon region 12 that is to be formed (size of the pores, direction, porosity) depend markedly upon the parameters set during the etching step, in particular upon:
the composition of the electrolyte in solution, and thus the percentage of HF present in solution, chosen between 5% and 48%;
the value of the anodization current, chosen between 5 and 1000 mA/cm²;
the etching time, chosen between 5 and 500 s;
the resistivity of the substrate (i.e., doping, already discussed previously); and
the temperature of the solution during the process, here carried out at room temperature.

The reaction of dissolution occurs immediately for the silicon regions of a P type, which may be anodized in the dark. Instead, for N-type silicon the presence of lighting is employed. It is thus possible to form the porous-silicon region selectively in the implanted region 10. The holes allow for the chemical reaction of dissolution of the crystalline silicon, which takes place at the interface between the silicon and the electrolytic solution.

Then, the step of FIG. 5 is carried out, in which the porous-silicon region 12 is transformed into a dielectric region 14, in particular of silicon oxide.

The porous nature of the porous-silicon region 12 enables transformation thereof with extreme ease into silicon oxide (also known as PSO, porous silicon oxide). Porous silicon presents, in fact, a high oxidation rate at low temperatures, an oxidation rate much higher than that of monocrystalline silicon. This is basically due to an extensive surface exposed to the process, which enables layers of porous silicon oxide to be obtained with a large thickness in a relatively short time.

For this purpose, a process of oxidation is carried out in a furnace at a high temperature (e.g., a rapid thermal process, at a temperature of 1000° C. with a temperature ascending ramp in an interval of 5-30 s, maintenance at the temperature in an interval of 1-10 min, and decrease to room temperature with a descending ramp down to room temperature in an interval of 30-60 s). This rapid-thermal-oxidation (RTO) process transforms the porous-silicon region 12 into the dielectric region 14, of low-density silicon oxide.

The thermal-oxidation process mentioned here likewise causes formation of an oxide layer on the side walls 6b of the trench 6, with a thickness d₃, measured along the axis X, of a few nanometers. Consequently, the internal free volume of the trench 6 is reduced.

This is followed (FIG. 6) by a step of formation, for example via chemical vapor deposition (CVD), of a layer of dielectric material 16 having a density higher than the density of the dielectric region 14, made, for example, of TEOS (alternatively, borophosphosilicate glass (BPSG), undoped Silicate Glass (USG), and silicone on glass (SOG) may be chosen), until the trench 6 is completely filled. The layer of dielectric material 16 fills the trench 6 and likewise deposits on the wafer 100.

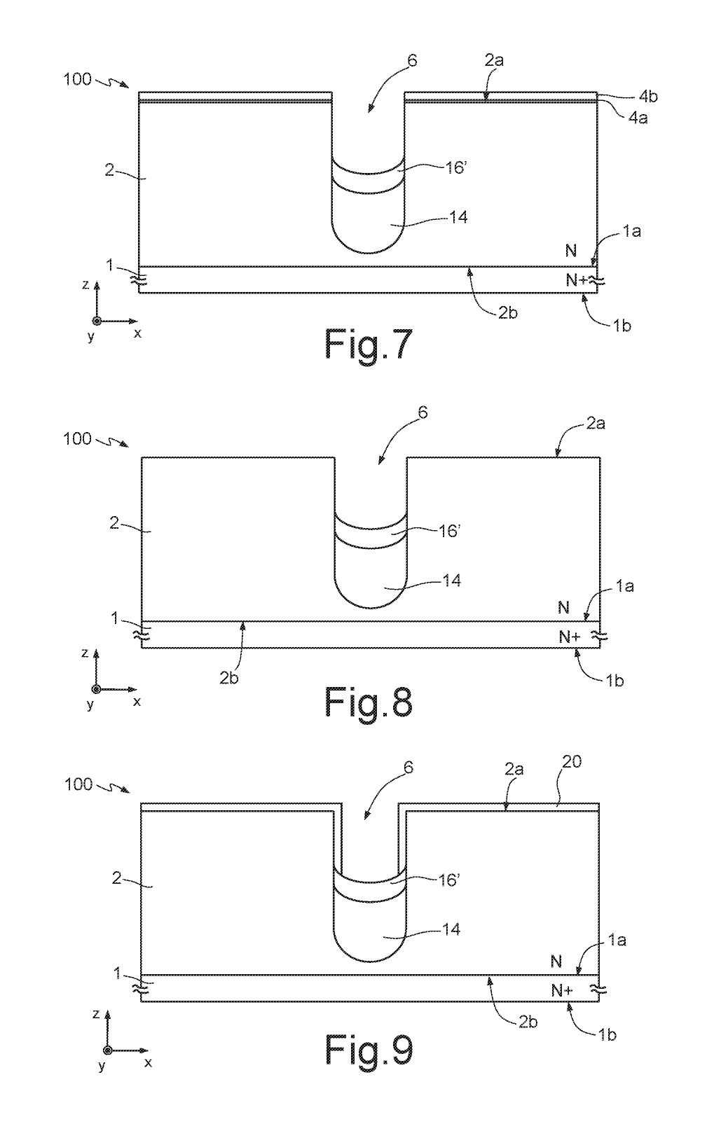

Next (FIG. 7), anisotropic plasma chemical etching is carried out for progressive removal of the layer of dielectric material 16 and of the third mask layer 4c (both of which are of TEOS in this example), as far as the second mask layer 4b, here of Si₃N₄, which functions as etch-stop layer. A portion 16′ of the layer of dielectric material 16 remains inside the trench 6, on the bottom side 6a, to cover completely, and protect, the dielectric region 14.

Optionally, a further etch in HF (wet etch) is made to complete removal of any possible oxide still present on the inner walls 6b of the trench 6.

Then (FIG. 8), two selective chemical etches are made for respective removal of the second mask layer 4b and the first underlying mask layer 4a, until the first side 2a of the structural layer 2 is exposed.

There then follows (FIG. 9) a step of formation, for example by thermal oxidation, of a gate-oxide layer 20 on the side walls 6b of the trench 6 (i.e., at the interface with the structural layer 2 exposed inside the trench 6) and on the first side 2a of the structural layer 2. The gate-oxide layer 20 has, for example, a thickness comprised between 10 and 50 nm.

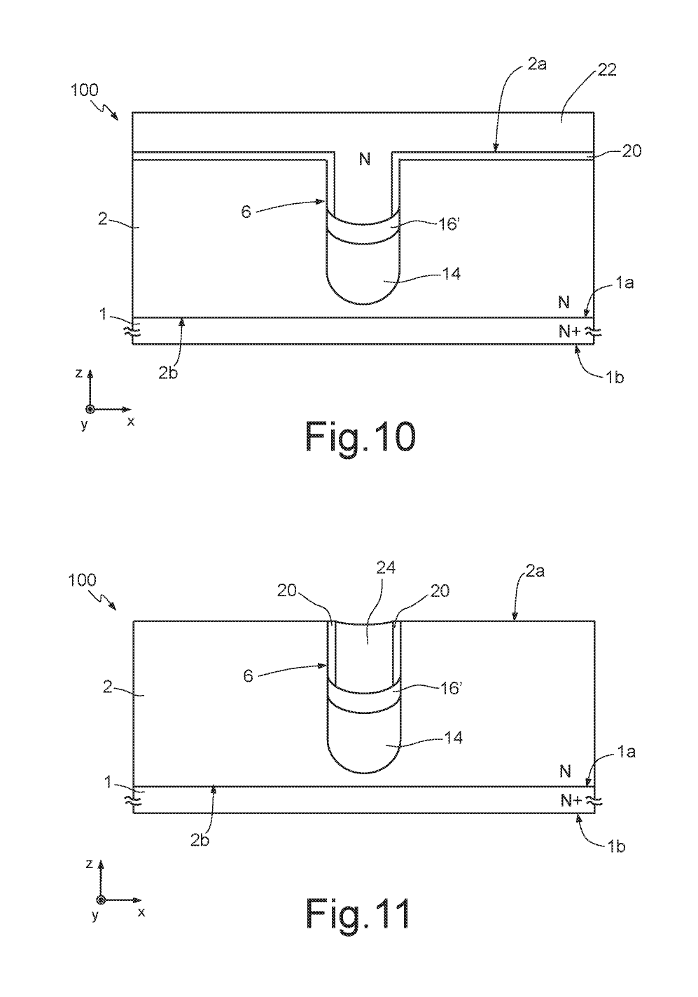

Next (FIG. 10), a layer of doped polysilicon 22, having the first conductivity type (N), and a doping level comprised between 10¹⁷ at./cm³ and 10¹⁹ at./cm³ is deposited, and (FIG. 11), a subsequent etching step is carried out for removal of the layer of doped polysilicon 22 from the front of the wafer 100 except for the trench 6. In other words, a trench conductive region 24, here of doped polysilicon N, extends in the trench 6 on the portion 16′, filling the trench 6 completely.

In a different embodiment, not illustrated, the trench conductive region 24 fills the trench 6 only partially, stopping at a distance from the first side 2a, measured along Z, comprised between 100 nm and the depth of the trench 6.

The trench conductive region 24 forms, at least in part, the gate electrode, which is electrically insulated from the structural layer 2 by the gate-oxide layer 20 (gate dielectric).

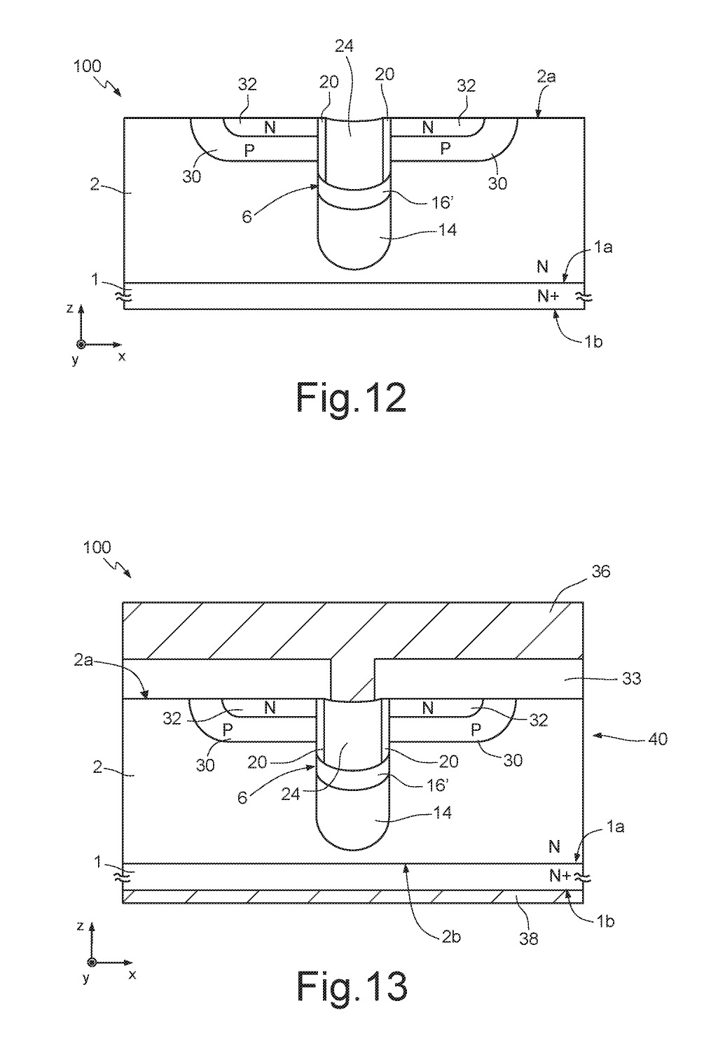

Then, with reference to FIG. 12, formed with known techniques of implantation of dopant species and diffusion are a body region 30, having the second conductivity (P), and one or more source regions 32, having the first conductivity (N), which are self-aligned to the trench 6 (here filled as described previously).

Processing of the wafer 100 may then continue (FIG. 13) with deposition of pre-metallization dielectric 33, etching of the latter for opening electrical contacts by photolithography so as to reach and expose respective surface portions of the gate electrode 24 and of the source regions 32, respective depositions of one or more metal layers that contact the gate electrode 24 and the source regions 32, and photolithographic definition of said metal layers 36 for completing formation of the source and gate electrodes (the cross-sectional view of FIG. 13 represents exclusively the gate metallization 36). A further deposition on the back of the wafer (on the second side 1b of the substrate 1) enables formation of a drain metallization 38.

In detail, the body region 30 is formed by implanting dopant species of a P type in order to obtain a doping level comprised approximately between 1·10¹⁷ ions/cm³ and 5·10¹⁷ ions/cm³. In greater detail, the body region 30 is formed in the structural region 2 for a depth in the direction Z comprised, for example, approximately between 0.5 μm and 1·0 μm.

The source regions 32 extend in the body region 30, facing the first side 2a of the structural region 2, for a depth in the direction Z comprised, for example, approximately between 100 nm and 150 nm. The source regions 32 each have a doping level, for example, of approximately 1·10²⁰ ions/cm³, and extend in top plan view, alongside the gate electrode 24, separated from the latter by the dielectric 20.

The gate and source metallizations 36 are formed by depositing conductive material on the wafer 100, in particular metal such as aluminum. Likewise, also the drain metallization 38 is formed by a step of deposition of conductive material, in particular metal, on the back of the wafer 100, thus completing formation of the drain terminal.

A vertical-conduction electronic device (here, a power MOSFET) 40 is thus formed. Thus, in use, an electric current may flow vertically (along Z) from the source regions 32 to the drain metallization 38, through the structural region 2 and the substrate 1. The electronic device 40 according to the present disclosure is, by way of example, one of the following: a vertical-conduction power MOS transistor, a power insulated-gate bipolar transistor (IGBT), or an MCT (MOS-Controlled Thyristor). Other applications may be envisaged, according to need.

From an examination of the characteristics of the disclosure provided according to the present disclosure the advantages that it affords are evident.

In particular, formation of the dielectric region 14 by oxidation of porous silicon is fast and far from costly, and considerably simplifies the manufacturing processes according to the prior art.

Further, said dielectric region 14 has a low value of dielectric constant, which enables reduction of the parasitic capacitance between the conductive polysilicon region 24 (gate) and the portion of the structural layer 2 that extends underneath the dielectric region 14.

The technical solution according to the present disclosure is likewise reliable, in so far as porous silicon oxide does not generate a significant stress at the interface with the structural layer 2. Consequently, no significant drifts of operating parameters or structural damages to the electronic device thus manufactured are noted during its service life.

Finally, the process according to the present disclosure is flexible, in so far as the depth that may be reached by the dielectric region 14 may be adjusted during the step of implantation and diffusion of the implanted region 10.

Finally, it is clear that modifications and variations may be made to what has been described and illustrated herein, without thereby departing from the scope of the present disclosure.

In particular, the present disclosure may be adapted for manufacturing an electronic device different from what is illustrated in the figures (for example, comprising a different configuration of the body region and/or of the source regions).

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A semiconductor electronic device comprising:
a semiconductor body having a first conductivity type and having a first side and a second side opposite to one another along an axis;
a body region, having a second conductivity type opposite to the first conductivity type, in the semiconductor body facing the first side;
a source terminal, having the first conductivity type, extending at least in part in the body region;
a drain terminal, having the first conductivity type, extending at the second side of the semiconductor body; and
a trench gate, which extends in the semiconductor body from the first side towards the second side, through the body region and the source region,
said trench gate including a dielectric region of porous silicon oxide buried in the semiconductor body, and a gate conductive region extending between the dielectric region of porous silicon oxide and said first side.

2. The device according to claim 1, further comprising a gate dielectric extending between the gate conductive region and the semiconductor body.

3. The device according to claim 1, wherein said trench gate further includes a protection region between the dielectric region of porous silicon oxide and the gate conductive region, the protection region separating the dielectric region of porous silicon oxide from the gate conductive region.

4. The device according to claim 3, wherein the protection region is of an electrically insulating material.

5. The device according to claim 1, wherein the gate conductive region is of doped polysilicon.

6. The device according to claim 1, chosen in the group comprising: a vertical-conduction power metal-oxide semiconductor (MOS) transistor, a power insulated-gate bipolar transistor, and an MOS-controlled thyristor.

7. A method for manufacturing a semiconductor electronic device, comprising:
forming, at a first side of a semiconductor body having a first conductivity type, a body region having a second conductivity type opposite to the first conductivity;
forming, at least in part in the body region, a source terminal having the first conductivity type;
forming a drain terminal at a second side, opposite to the first side, of the semiconductor body; and
forming a trench extending from the first side of the semiconductor body through the body region and the source region,
forming a porous-silicon region in the semiconductor body at a bottom side of the trench and in spatial continuation of the trench; and
oxidizing the porous-silicon region to form a dielectric region of porous silicon oxide.

8. The method according to claim 7, wherein forming the porous-silicon region comprises:
implanting dopant species that have the second conductivity type in the semiconductor body, at the bottom side of the trench;
thermally activating said implanted dopant species, to form an implanted region; and
carrying out an electrochemical reaction designed to transform said implanted region into the porous-silicon region.

9. The method according to claim 8, wherein implanting the dopant species includes carrying out a plurality of successive implantations with different implantation energies in the range comprised between 100 keV and 1000 keV and with the same implantation dose comprised between 5·10¹⁴ and 5·10¹⁵ at./cm³.

10. The method according to claim 8, wherein carrying out the electrochemical reaction comprises:
inserting said semiconductor body in an aqueous electrolytic solution that includes hydrofluoric acid in a percentage comprised between 5% and 48%;
maintaining the electrolytic solution at room temperature; and
applying an anodization current having a value comprised between 5 mA/cm² and 1000 mA/cm².

11. The method according to claim 8, wherein forming the porous-silicon region further comprises carrying out a thermal-oxidation process at a temperature comprised between 900° C. and 1050° C., with an ascending ramp in temperature in an interval of 5 to 60 s, and maintenance of constant temperature in an interval of 1 to 10 min.

12. The method according to claim 7, further comprising forming a gate dielectric at side walls of the trench, the gate dielectric being configured to insulate the gate conductive region from the semiconductor body.

13. The method according to claim 7, further comprising forming a protection region on the dielectric region of porous silicon oxide, wherein forming the gate conductive region comprises forming the gate conductive region on the protection region so that the gate conductive region is separated from the dielectric region of porous silicon oxide by the protection region.

14. The method according to claim 13, wherein forming the protection region comprises depositing insulating material in the trench.

15. A semiconductor electronic device comprising:
a semiconductor body having a first side and a second side opposite to one another;
a body region in the semiconductor body;
a source region in the semiconductor body;
a drain region in the semiconductor body; and
a trench gate extending in the semiconductor body from the first side towards the second side, the trench gate including a dielectric region of porous silicon oxide buried in the semiconductor body, and a gate conductive region extending between the dielectric region of porous silicon oxide and said first side.

16. The device according to claim 15, further comprising a gate dielectric extending between the gate conductive region and the semiconductor body.

17. The device according to claim 15, wherein said trench gate further includes a dielectric protection region between the dielectric region of porous silicon oxide and the gate conductive region, the protection region separating the dielectric region of porous silicon oxide from the gate conductive region.

18. The device according to claim 17, wherein the protection region has a higher density higher than the dielectric region of porous silicon oxide.

19. The device according to claim 15, wherein the trench gate extends in the semiconductor body through the body region and the source region.

20. The device according to claim 15, wherein:
the semiconductor body has a first conductivity type;
the body region has a second conductivity type, opposite to the first conductivity type, and faces the first side;
the source terminal has the first conductivity type and extends at least in part in the body region; and
the drain terminal has the first conductivity type and extends at the second side of the semiconductor body.
